(19) United States
(12) Patent Application Publication
(10) Pub. No.: US 2026/0133275 A1
(43) Pub. Date: May 14, 2026

(54) Computer-Implemented Method for Processing a Magnetic Resonance Data Set of an Acquisition Area, Image Processing Facility, Computer Program and Electronically Readable Data Carrier

(71) Applicant: Siemens Healthineers AG, Forchheim (DE)

(72) Inventors: Mario Zeller, Erlangen (DE); Christian Meixner, Erlangen (DE)

(73) Assignee: Siemens Healthineers AG, Forchheim (DE)

(21) Appl. No.: 19/388,621

(22) Filed: Nov. 13, 2025

(30) Foreign Application Priority Data
Nov. 14, 2024 (DE) 10 2024 210 933.9

(51) Int. Cl. G01R 33/56; G01R 33/50; G01R 33/561; G06T 11/00

(52) U.S. Cl. CPC G01R 33/5608; G01R 33/50; G01R 33/5615; G06T 12/10; G06T 12/20; G06T 2211/441

(57) ABSTRACT

The disclosure relates to a computer-implemented method for processing a magnetic resonance data set of an acquisition area, which is based on an acquisition in an examination procedure in a magnetic resonance facility with a magnetic resonance sequence in which multiple echoes are acquired in an echo train, in particular after a common radio-frequency excitation pulse. For the magnetic resonance data set, a path data set describing the signal path of the measured magnetic resonance signal over an acquisition period, in particular the echo train, in the magnetic resonance sequence is determined in the k-space. A trained image processing function for determining a result data set is transferred together with the magnetic resonance data set as input data.

### CROSS REFERENCE TO RELATED APPLICATIONS

This patent application claims priority to German Patent Application No. 102024210933.9, filed Nov. 14, 2024, which is incorporated herein by reference in its entirety.

### BACKGROUND

The disclosure relates to a computer-implemented method for processing a magnetic resonance data set of an acquisition area, which is based on an acquisition in an examination procedure in a magnetic resonance facility with a magnetic resonance sequence in which multiple echoes are acquired in an echo train, in particular after a common radio-frequency excitation pulse. In addition, the disclosure relates to an image processing facility, a computer program and an electronically readable data carrier.

Magnetic resonance imaging is now an established tool in medical technology. Since relatively long acquisition times frequently exist in magnetic resonance imaging, various approaches have already been proposed for reducing these, for example by increasing patient throughput and/or permitting the improved mapping of dynamic procedures and/or increasing the robustness against movement. To this end, magnetic resonance sequences have firstly been developed in order to be able to measure more quickly, these including not only magnetic resonance sequences with an ultra-short echo time, but also those in which a large number of readout modules, in which for example k-space rows can be read out in each case, are used after a common radio-frequency excitation pulse of a corresponding excitation module. Such an operational sequence is also referred to as an echo train, an echo being read out in each readout module. The respective echo can for example be generated by a special preparation module, for example comprising a radio-frequency refocusing pulse.

A known class of such magnetic resonance sequences is turbo spin echo sequences (TSE sequences), which use RARE technology (Rapid Acquisition with Relaxation Enhancement). Use is made here of a series of refocusing pulses, in particular with a flip angle of 180°, in order, after a radio-frequency excitation pulse, for example with a flip angle of 90°, to provide an echo train whose refocused echoes are measured in the corresponding readout modules. Different phase-encoding gradients are employed in each case for the acquisition of different k-space rows.

One example of a TSE sequence is the so-called SPACE sequence (Sampling Perfection with Application optimized Contrast using different flip angle Evolution). This is used in particular for 3D imaging (3D SPACE). It is characterized by among other things long echo trains (for example more than 100 echoes), a short echo interval, at least partially reduced flip angles (for example to prevent heating of tissue) and optimized, efficient k-space trajectories.

In all acquisition methods with long echo trains, various causes can particularly lead to a weighting and thus implicit filtering of the magnetic resonance data in the sampled k-space. In other words, deviations of the actual measurement result from the magnetic resonance signal to be ideally measured (for example at the nominal echo time or in a first echo after the radio-frequency excitation pulse) or a reference can occur, due to different effects at different times at which sampling is carried out at a k-space position, in particular a relaxation (where appropriate manipulated) of excited echo signals in the course of the measurement. Due to the T2/T2* decay, later echoes in an echo train for example have a lower intensity than earlier echoes. Also, a variation of the flip angles over the echo train in order to achieve storage and recovery of signal along the longitudinal magnetization leads to a change in the intensities over time. Depending on the acquisition parameters set, the k-space trajectory can moreover change (reordering), for example to achieve a desired echo time. However, the k-space trajectory ultimately defines when a k-space position is sampled.

However, the differences in intensity in the k-space do not have a relevant effect on the reconstruction of a magnetic resonance image in the image space, in particular due to or comprising a Fourier transform, from a corresponding magnetic resonance data set, since potential jumps or edges in intensity are rather small within the sampled k-space between adjacent k-space positions.

A further possibility for saving acquisition time and nevertheless providing high-quality magnetic resonance images is to subsequently increase the spatial resolution, known as “super-resolution”. A lower spatial resolution means that a smaller proportion of the k-space around the center of the k-space is to be sampled, in order to acquire a magnetic resonance data set. A resolution enhancement function can then be applied to a basic image reconstructed from the magnetic resonance data set in the image space, in order to enhance the spatial resolution from a first spatial resolution of the basic image to a second spatial resolution, for example to double it.

Resolution enhancement functions, in particular super-resolution functions, as well as other application functions, for example reconstruction algorithms of undersampling, are frequently trained using machine learning. For example, neural networks and/or comparable artificial intelligence architectures can be employed.

When training application functions, in particular resolution enhancement functions, training data is often employed which originates from a particular signal path. For example, it is known for the central k-space part to be excised from a high-resolution k-space data set whose Fourier transform forms the training output data set, i.e. the basic truth whose Fourier transform forms the training input data set. The k-space data set was for example acquired in single echo imaging and thus does not map the signal path in a multi-echo measurement, in particular the T2 decay occurring during the echo train. If the trained resolution enhancement function is then subsequently applied to a magnetic resonance data set which was acquired with a magnetic resonance sequence to be read out multiple echoes after a common radio-frequency excitation pulse, a deviating point spread function (PSF) may be present, which can lead to resolution loss and/or edge overemphasis. In other words, known trained resolution enhancement functions do not model the variable T2 decay effects in multi-echo imaging, in particular TSE sequences, resulting in a loss of image quality.

To achieve improvements in this respect, it has been proposed to improve the training of the resolution enhancement function in order to achieve a general “T2 deblurring”. Thus in an article by Z. Chen et al., “Physics-informed deep learning for T2-deblurred superresolution turbo spin echo MRI”, Magn. Reson. Med. 90(2023 ), pages 2362 to 2374, it is proposed to train a model, i.e. a function, specifically with physically realistic resolution degradation (asymmetrical T2 weighting of the raw high-resolution k-space data).

In an article by Z. Zhou et al., “Neural network enhanced 3D turbo spin echo for MR intracranial vessel wall imaging”, Magnetic Resonance Imaging 78(2021 ), pages 7 to 17, it is proposed, in an acquired TSE image, to reduce blurring induced by relaxation by means of a CNN, in order to increase the general image quality of TSE acquisitions.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a flowchart of a method according to an exemplary embodiment.

FIG. 2 shows sections from the operational sequence of an examination procedure with a multi-echo magnetic resonance sequence, according to an exemplary embodiment.

FIG. 3 shows an example signal path over an echo train, according to an exemplary embodiment.

FIG. 4 shows a sequence diagram of a HASTE echo train with additional measurements, according to an exemplary embodiment.

FIG. 5 schematically shows the structure of a preparation function, according to an exemplary embodiment.

FIG. 6 shows an operational sequence for training a preparation function, according to an exemplary embodiment.

FIG. 7 shows a flowchart of a method according to an exemplary embodiment.

FIG. 8 shows the functional structure of an image processing device according to an exemplary embodiment.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to specify a possibility for increasing the quality of the image-processing results of multi-echo magnetic resonance data sets, in particular in the case of super-resolution. This object is inventively achieved by a computer-implemented method, an image processing facility, a computer program, and an electronically readable data carrier (e.g., computer-readable media).

In an exemplary embodiment, a method for processing a magnetic resonance data set of an acquisition area may include: for the magnetic resonance data set a path data set describing the signal path of the measured magnetic resonance signal over an acquisition period, in particular the echo train, in the magnetic resonance sequence is determined in the k-space; and is transferred to a trained image processing function for determination of a result data set together with the magnetic resonance data set as input data.

It is consequently proposed to determine the corresponding signal path, in particular thus describing the T2 decay processes and further factors influencing the intensity over the course of the magnetic resonance sequence, for each magnetic resonance data set to be processed, and to process it using artificial intelligence in the form of the trained image processing function, such that the individual intensity behavior over the specific acquisition procedure can be taken into account, leading to a significant improvement in quality in the final processing result, whether directly the result data set or the output data of an application function in which the result data set is included. Thus deblurring by means of decay information determined individually for a magnetic resonance data set in the form of the path data set and artificial intelligence in the form of the trained image processing function are proposed, in order thus to obtain an improved image quality, a reduction in artifacts and in particular an improved sharpness in resolution enhancement (super-resolution).

In general, a trained function maps cognitive functions which human beings associate with other human brains. Thanks to training based on training data (machine learning), the trained function is able to adapt to new circumstances and to detect and extrapolate patterns. Another expression for “trained function” is “trained machine learning model”.

Generally speaking, parameters of a trained function can be adjusted thanks to training. In particular, supervised learning, semi-supervised learning, unsupervised learning, reinforcement learning and/or active learning can be used. In addition, representation learning (also known as “feature learning”) can also be employed. The parameters of the trained function can be adjusted, in particular, iteratively using multiple training steps. A particular cost function can be minimized in the training. For example, the backpropagation algorithm can be employed when training a neural network.

A trained function can, for example, comprise a neural network, a support vector machine (SVM), a decision tree, and/or a Bayesian network, and/or the trained function can be based on k-means clustering, Q-learning, genetic algorithms, and/or assignment rules. In particular, a neural network can be a deep neural network, a convolutional neural network (CNN), or a deep CNN. In addition, the neural network can be an adversarial network, a deep adversarial network and/or a generative adversarial network (GAN).

Particularly advantageously, the trained image processing function may comprise at least one CNN. A convolutional neural network (CNN) is a neural network which uses a convolution operation instead of general matrix multiplication in at least one of its layers, the so-called convolution layer. In particular, a convolution layer can perform a scalar product of one or more convolution kernels with the incoming data/images of the convolution layer, wherein the entries of the one or more convolution kernels are the parameters or weights that are adjusted by training. In particular, the inner Frobenius product and the ReLu activation function can be used. A CNN can comprise additional layers, for example, pooling layers, fully connected layers, and normalization layers. Input images or data sets can be processed in an extremely efficient way using CNN, since a convolution operation can extract a wide variety of data features on the basis of different kernels, so that by adjusting the weights of the convolution kernels, the relevant data features can be found during the training. In addition, on the basis of sharing the weights in the convolution layer kernels, fewer parameters need to be trained, so that overfitting in the training phase is prevented and faster training or a larger number of layers in the CNN is allowed, thus increasing the performance of the network.

It should be noted at this point that in the context of this description a signal path should be understood to mean that the data of the path data set describes a comparable measure for signal intensity, in particular taking into account the T2 signal decay and where appropriate further effects such as signal recovery by flip angles, over the acquisition period, in particular the echo train, and thus, if the sequence of sampling the k-space information, i.e. the k-space trajectory, where appropriate after reordering, is known, also in the k-space. In other words for example the path data set assigns to k-space positions, in particular at least some of the sampled k-space positions, a measure for the signal intensity compared to a reference, said measure resulting from the temporal signal path over acquisition period, for example the echoes, in particular comprising at least its T2 relaxation and optionally at least one further effect (for example varying flip angles), and the respective sampling time in the acquisition period, in particular in the echo train, due to the sampling order. Specifically, the path data set can for example be a decay matrix in which a decay value is assigned to each sampled k-space position as a measure for signal intensity, for example in the form of a weighting with regard to a reference path and/or one of the echoes, in particular the first echo (which as a reference would correspond to a single echo acquisition).

The disclosure is described below mainly with reference to a magnetic resonance sequence, in which multiple echoes are acquired in an echo train (as the acquisition period), in particular after a common radio-frequency excitation pulse, since particularly advantageous results have been shown here. However, it is absolutely also possible to employ the disclosure in other areas of application in which a signal path can occur that differs significantly from other signal paths of other magnetic resonance sequences, but for which the same image processing measures, in particular of artificial intelligence, are to be applied. One example is magnetic resonance sequences with an ultra-short echo time (UTE sequences), in which a strong decay of the signals can already be observed along a single k-space row to be sampled. This will also be briefly discussed in a few examples.

To determine the path data set a particularly advantageous development is proposed, namely that the path data set is determined at least in part from measured data of a measurement of the examination procedure. A measurement has the particular advantage of actually capturing the individual measurement circumstances and properties of the acquisition procedure of the acquisition area. It has been recognized that in many acquisition procedures, in particular in the context of the use of many magnetic resonance sequences with an echo train, comparable partial measurements are either performed in any case at different times of the echo train with regard to the measured signal intensity over at least one of the echo trains, or can be performed at least without any problems, in particular also additionally. From this, the signal path can then be determined in time over the echo train, from which, taking into account the sampling sequence when acquiring the magnetic resonance data, the signal path can also be determined in the k-space.

For example, in a particularly advantageous configuration it can be provided that magnitude data of a phase correction scan with the magnetic resonance sequence acquired without phase-encoding gradients can be used as the measured data. In the context of the present disclosure, it was recognized that in many cases a phase correction scan is acquired for example in TSE sequences as the magnetic resonance sequence, prior to the actual measurement of the magnetic resonance data to correct eddy current effects. This partial measurement of the acquisition procedure may comprise a complete echo train and takes place without phase-encoding, so that the individual echoes are directly comparable with one another as regards the signal decay. Normally only the phase data from such a phase correction scan is used. In accordance with the disclosure, it is now proposed to extract the path profile from the magnitude data which is acquired in the phase correction scan, and which describes the signal path during the echo train.

Additionally, or alternatively, it can be provided that additional measured data of particular echoes, in particular comprising the first and the last echo, of an echo train, which was acquired without phase-encoding gradients, and/or repetition measured data for at least one k-space section which was measured multiple times during the echo train, can be used as measured data. In magnetic resonance sequences or acquisition procedures in which no phase correction scan is performed, for example, in the HASTE sequence, it can consequently be provided that non-phase-encoded echoes are measured in at least one echo train in which magnetic resonance data is measured in particular. Since the center of the k-space is in any case measured without phase-encoding, the first and the last echo can for example, likewise be acquired without phase-encoding, so that it is possible to calculate an exponential decay profile from these at least three data points, so that signal intensities for other k-space positions can be interpolated and thus a signal path can be determined. Alternatively, or additionally, it is also conceivable for the same phase-encoding to be employed multiple times, for example, to measure the same k-space row multiple times in order to obtain vertices for an interpolation and/or extrapolation.

It should be noted at this point that in such magnetic resonance sequences, which use echo trains with multiple echoes, a k-space row is normally acquired for each echo. In principle, other partial k-space trajectories for acquisition modules of individual echoes are also conceivable. It is in principle conceivable for the decay to be resolved along k-space rows (normally kₓ), but the differences in the weighting resulting from the loss are frequently assumed to be smaller here, so that in the path data set the k-space positions of a k-space row can be assigned a common signal path value (decay value), in particular in the sense of a weighting valid for the entire k-space row. It is possible, for example, to determine averaged signal intensities over the k-space rows, i.e., the readout direction, and to use the averaged signal intensities over the echo train to derive the signal path along at least one phase-encoding direction.

If only individual echoes are considered, for example, in the case of the UTE sequences, the path data set can, for example, be determined by the measurement of a free induction decay (FID), which means by recording a magnetic resonance signal without any encoding in the readout direction. The decay can then be determined from the signal envelope.

The path data set can generally also be determined at least in part by a computation, modeling, and/or simulation, wherein at least one item of relaxation information about the relaxation in the acquisition area is used. In this case, a calculation or the like may take place on the basis of the measured data, so that, as already set out above, it can be provided that the path data set is extrapolated and/or interpolated, using a decay model, from vertices given by the additional measured data together with measured data of the center of the k-space and/or by the repetition measured data. As already mentioned, an exponential decay model can, for example, be used here.

However, it is also conceivable for more remote measured data, so to speak, to be used or even to make assumptions about the acquisition area in order to enable a determination of the path data set using a calculation, a model and/or a simulation. For example, it can be provided that the relaxation information may comprise at least one T2 and/or T2* relaxation time, which can be used as a basis for the decay.

The relaxation information can, for example, be determined, at least in part, from a map and/or relaxometry measurement of the acquisition area previously measured, particularly in the context of the examination procedure. Consequently, relaxometry methods and/or mapping methods can be used. If, for example, a T2 map of the acquisition area is present, a mean decay curve for the entire k-space can be calculated from the layer-by-layer T2 value distribution, or else a spatially resolved determination can take place, in this case, layer-by-layer.

Furthermore, it can also be provided that the relaxation information is determined from an assignment rule that assigns at least some of the relaxation information to information about the anatomical position of the acquisition area and/or about the material composition of the acquisition area. Such an assignment rule can also use at least one sequence parameter of the magnetic resonance sequence as an input value, for example to know the radio-frequency excitation. For example, a signal path can be determined from a lookup table containing typical decay values based on the body region of the acquisition area and set sequence parameters.

The path data set is determined resolved in at least one direction of the k-space, for example in the at least one phase-encoding direction. In an exemplary embodiment, the path data set, such as from the measured data, may be determined along a readout direction of the magnetic resonance sequence and/or for different local coil elements of a local coil array used. It is consequently possible to provide a resolution along the readout and/or coil dimension at least in an intermediate step to provide as much information as possible as a path data set.

In general, it can be advantageous to provide the path data set in the same dimensionality and/or size as the magnetic resonance data set as input data for the trained image processing function, since then a simpler common processing and/or structure of the trained image processing function is possible.

In an exemplary embodiment of the present disclosure, it can be provided that the trained image processing function is a preparation function, which as output data (and thus a result data set) outputs a corrected magnetic resonance data set whose signal path corresponds to a reference path, in particular the signal path of a single echo acquisition. In this case, a preparation function is therefore used to evaluate the magnetic resonance data set with regard to the signal path, i.e. in particular the signal decay over the echo train or the resulting weighting, corrected so that the corrected magnetic resonance data set provided as output data corresponds to one which would be obtained with a reference path (for example single echo imaging). In particular, the reference path is determined by the signal path in the acquisition or other determination of application function training data which was used for training a trained application function to be employed below.

In other words, it can be provided that the corrected magnetic resonance data set is used as input data for a trained application function, in particular a resolution enhancement function, wherein the application function is trained with application function training data sets whose application function training input sets have the reference path. If for example a resolution enhancement function, in particular a super-resolution function, is trained with application function training data which is based on single echo imaging, in which consequently the T2 signal decay and where appropriate further effects, such as those that lead to weighting effects in multi-echo imaging, do not occur, the effect of the signal decay can be calculated by means of the trained preparation function and thus has no negative influence on the effect of the application function, here the resolution enhancement function. This results in better image quality and a reduced number of artifacts.

It should be noted at this point that a trained preparation function is used in this case in order to reduce or subtract the weightings in the magnetic resonance data set occurring due to the signal path. At least in theory it would be possible to correct the magnetic resonance data set by division by the weighting-specifying path data set. However, in practice, magnetic resonance data has noise, wherein the noise level remains the same over the k-space, while the signal (or its weighting) varies. A direct modification of the magnetic resonance data set with the path data set would therefore be accompanied by a strong increase in the noise level. Hence it is proposed to employ machine learning to determine a corrected magnetic resonance data set without increasing the noise.

The preparation function can expediently comprise a convolutional neural network, in particular a U-Net. A U-Net is a CNN which was originally developed for image segmentation, cf. the article by O. Ronneberger et al., “U-Net: Convolutional Networks for Biomedical Image Segmentation”, arXiv:1505.04597, and is also eminently suitable for various other image-to-image processing tasks, such as the modification presented here with regard to the signal path or signal decay, insofar as it leads to a weighting for different echoes or k-space points along a k-space row. In a specific configuration, for example, the original magnetic resonance data set (in the k-space) and the path data set adjusted to the same matrix size, in particular as a decay matrix, can likewise be transferred in the k-space for the interference process, for example, of the preparation function comprising a U-Net as input data, wherein the output layer then outputs a k-space matrix corrected by the decay, namely the corrected magnetic resonance data set. The k-space corrected to a reference path can then be transferred to the application function, in particular comprising at least one further network, where appropriate also after an at least partial Fourier transform into the image space. Such is in particular expedient if the application function is a resolution enhancement function. The application function can also, for example, be a reconstruction function of parallel imaging. Other network architectures for the preparation function are of course also conceivable.

Various approaches are conceivable in order to train the preparation function. In a first possible exemplary embodiment, it can be provided that preparation function training input data sets can be acquired in a first training measurement and preparation function training output data sets with a second training measurement using the reference path, in particular as a single echo measurement. For example, it can thus be provided that a training pair consisting of preparation function training input data set and preparation function training output data set is determined, in that a first training measurement with an echo train acquisition and a second training measurement with a single echo acquisition, but the same timing, i.e. the same echo time, are performed at the same acquisition area, as stationary and unchanged as possible, in particular directly consecutively. For example, initially a TSE sequence with turbo factor 8 and then the same magnetic resonance sequence can be performed as a single echo measurement with the same echo time (with turbo factor 1, so to speak). Here, a particularly expedient development provides that stationary measurement objects, in particular phantoms and/or fruits and/or vegetables and/or dead tissue, are used to perform the training measurements to obtain training input data and training output data in consecutive measurement processes. In other words, in order to prevent physiological effects in test subjects, objects with relaxation times and structures comparable to those of the human body can be used. Examples include anatomical phantoms, fruits and/or vegetables. Additionally or alternatively, it can also be provided that at least some of the preparation function training data is determined by simulation, in particular Bloch simulation using the reference path.

As regards training measurements, it should be noted as regards multi-echo measurements that here—as also with regard to the other possibilities for determining training data—the reference path does not necessarily have to correspond to a single echo measurement. For example, other training output data sets can also be generated, which merely have a smaller decay than the corresponding training input data sets. In other words, non-perfect target k-spaces can also be generated, for example by reducing the turbo factor in TSE measurements. For example, training input data with a turbo factor of 16 can be acquired in the first training measurement, and training output data with a turbo factor of 4 (which then defines the reference path) in the second training measurement. For HASTE sequences, parallel imaging can also be employed to reduce the echo train length during the acquisition of training output data. In this case for example, in the first training measurement an acquisition of training input preliminary data sets can be carried out with a twofold acceleration due to parallel imaging, while in the second training measurement an acquisition of training output preliminary data sets (target k-space) can be performed with a fourfold acceleration of parallel imaging. The preliminary data sets are then reconstructed in order to obtain the corresponding training data set with reconstruction functions of parallel imaging. In other words, the reconstructed k-spaces then serve as input and output k-spaces for training the preparation function.

As regards the UTE sequences discussed, training of the preparation function can, for example, take place using acquisitions with a low field strength of the constant magnetic field, for example, 0.5 to 0.6 T, where a correspondingly smaller, i.e., slower, decay is present. A simulated signal curve for higher field strengths can then be imprinted on the measurement results.

In an exemplary embodiment, the determination of preparation function training data sets may be provided that: a synthesized and/or at least substantially noise-free basic data set of the reference path is provided in the k-space, at least one training path data set is applied to the basic data set to determine a modification data set, and the modification data set and the basic data set are provided with noise, in particular Gaussian noise, to obtain a preparation function training input data set or a preparation function training output data set.

Consequently, this here assumes an existing, low-noise or even noise-free basic data set of the reference path in the k-space, whereby such a basic data set can be synthesized for example, in particular by simulation, but can also be obtained in other ways, for example by using denoising methods and the like. The basic data set can then be modified, in particular multiplied, by a plurality of different training path data sets describing signal paths over the k-space, in particular i.e. decay matrices, in order then to overlay the basic data set and the modification result with a noise, in particular Gaussian noise, with the same distribution, in order to create pairs of preparation function training input data sets and preparation function training output data sets. In this way, a simple basic generation or extension of training data is possible. It should be noted that the preparation function can also be trained in this way as regards denoising, if a noise of lower amplitude or lower noise level is used for the modification data set.

The possibilities for training the preparation function (or other functions) described here can also be the subject of a separate preparation method, which can be performed independently of the generally described processing method, in which the respective trained function is provided for its completion. For example, a preparation method for a trained preparation function, as introduced above, is conceivable, in which, for training the preparation function:
to determine preparation function training data sets
   a synthesized and/or at least substantially noise-free basic data set of the reference path is provided in the k-space,
   at least one training path data set is applied to the basic data set to determine a modification data set, and
   the modification data set and the basic data set are provided with noise, in particular Gaussian noise, to obtain a preparation function training input data set or a preparation function training output data set;
preparation function training input data sets are acquired in a first training measurement and preparation function training output data sets with a second training measurement using the reference path, in particular as a single echo measurement; and/or
at least some of the preparation function training data is determined by simulation, in particular Bloch simulation using the reference path.

Training of the preparation function may be carried out using the preparation function training data sets obtained. The trained preparation function may be, for example, provided via an interface. Such a preparation method can be provided by a provision system and/or stored as a provision computer program on an electronically readable provision data carrier.

In a second configuration variant of the present disclosure, alternative to the use of a preparation function, it can be provided that the trained image processing function is an application function, such as a resolution enhancement function, to determine a result data set as output data. Consequently, it is also possible to transfer the path data set, for example as a decay matrix in the k-space, which can specify a decay value for each sampled k-space position (e.g., a weighting) as additional input data to an architecture existing for a particular purpose, consequently the trained application function. In other words, for example, an existing super-resolution function architecture or another existing trained resolution enhancement function architecture of machine learning can be modified so that it accepts a path data set, for example a decay matrix, as additional input data in the input layer. A corresponding architecture can operate both in the k-space and in hybrid or image space. For example, the path data set can be present in the k-space, but the magnetic resonance data can be in the image space or in a hybrid space.

As regards the training of such an application function, such as obtaining corresponding application function training data sets, comprising application function training input data sets and application function training output data sets, comparable approaches to what was explained as regards the preparation function can be used. In particular, training measurements can likewise be performed, wherein stationary objects, such as phantoms and/or fruits and/or vegetables and/or dead tissue, may be used to perform training measurements to obtain training input data and training output data in consecutive measurement operations.

The inventive method can also be employed generally both for two-dimensional sampling magnetic resonance sequences and for three-dimensional sampling magnetic resonance sequences.

Besides the processing method, the present disclosure also relates to an image processing facility, having a computing facility with at least one processor and at least one storage means. The computing facility may include, for processing a magnetic resonance data set of an acquisition area, which is based on an acquisition in an examination procedure in a magnetic resonance facility with a magnetic resonance sequence in which multiple echoes are acquired in an echo train, such as after a common radio-frequency excitation pulse:
a determination unit to determine a path data set describing the signal path of the measured magnetic resonance signal over an acquisition period, such as the echo train, in the magnetic resonance sequence in the k-space for the magnetic resonance data set, and
a processing unit to determine a result data set by means of a trained image processing function, which uses the path data set together with the magnetic resonance data set as input data.

All explanations regarding the inventive method can be transferred analogously to the inventive image processing facility and vice versa, so that the advantages already mentioned can also be obtained with the image processing facility.

In the computing facility, function units are formed by hardware and/or software in order to perform steps of the inventive processing method. Further function units can be provided for the implementation of further configurations of the processing method. For example, the computing facility can also comprise an application unit for applying an application function, and/or a training unit. The training unit can comprise a subunit for determining training data sets.

The inventive image processing facility can particularly advantageously be integrated into a magnetic resonance facility. The computing facility can then be provided as part of a control facility of the magnetic resonance facility. The control facility can also have a sequence unit which can control the acquisition of the magnetic resonance data set as well as the acquisition of measured data in general, in particular also additional measured data and/or repetition measured data. The sequence unit can also be designed to perform first and second training measurements to determine training data sets.

An inventive (processing) computer program can be loaded directly into a storage means of a computing facility of an image processing facility and has program means such that when the computer program is executed on the computing facility, said computing facility is caused to perform the steps of an inventive (processing) method. The computer program can be stored on an inventive electronically readable data carrier, which consequently may comprise control information stored thereon, which may comprise at least one inventive computer program and is designed such that when the data carrier is used in a computing facility of an image processing facility, it is designed to perform an inventive method. In particular, the data carrier can be a non-transient data carrier, for example a CD-ROM.

In the following, exemplary embodiments of the present disclosure are explained in relation to two-dimensional sampling magnetic resonance sequences. In order to acquire a magnetic resonance data set in at least one echo train, the k-space is sampled in accordance with a sampling sequence, specifically a k-space trajectory, along k-space rows, wherein in each echo a k-space row is sampled along different k-space positions. However, what is described here can also be transferred to three-dimensional sampling magnetic resonance sequences and/or magnetic resonance sequences sampling along other sampling patterns.

If multiple echoes have been read out in multiple readout modules in an echo train, there is a certain signal path present, in particular at least due to the T2 decay, over the echo train. In other words, a different magnetic resonance signal is measured depending on how many echoes a given k-space row along the echo train are actually sampled in accordance with the sampling order. This effect can be understood as a weighting. Besides the T2 decay, relevant effects can also arise due to variable flip angles over the echo train. Different signal intensities depending on when sampling occurs along an echo train do not occur with single echo acquisitions. At the same time, the signal paths differ between different specific magnetic resonance sequences, in particular also as a function of the sampling sequence in the k-space. This can influence the quality of processing results which are determined by in particular employing application functions trained by means of machine learning, in particular if these are designed or trained for other, in particular at least substantially constant or unvarying signal paths over the sampled k-space. Two exemplary embodiments are presented below in order to bring about improvements in this respect.

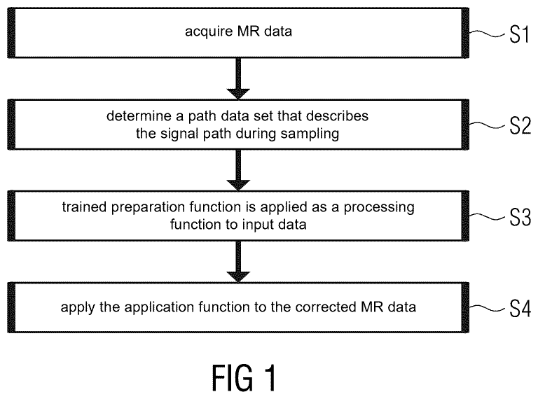

In the first exemplary embodiment in FIG. 1 magnetic resonance data of an acquisition area, for example of a patient, is acquired in a step S1, initially in the context of an examination procedure, wherein a magnetic resonance sequence is used, and after a common radio-frequency excitation pulse multiple echoes are read out in an echo train. Measured data is also acquired here, particularly through the magnetic resonance sequence, and can be used in step S2 to determine a path data set that describes the signal path during sampling in the k-space. In this case the measured data describes the signal path, in particular the T2 decay, during the echo train, from which a signal path over the k-space follows, with knowledge of the respective sampling order in the at least one echo train which was used for the acquisition of the magnetic resonance data set.

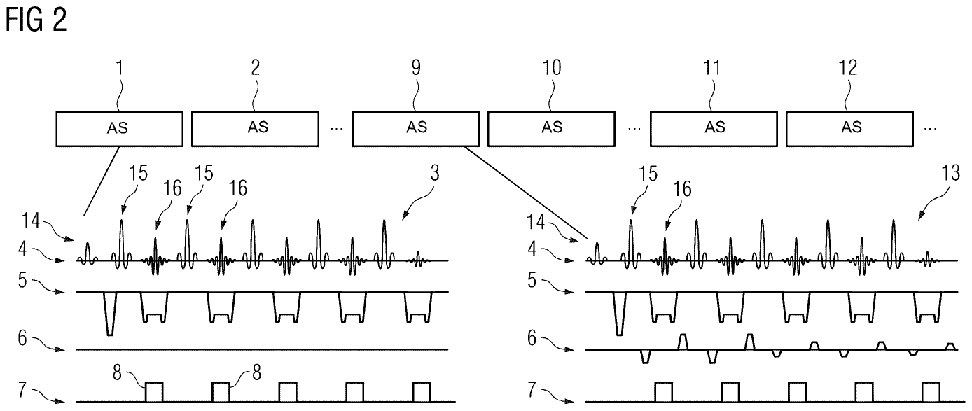

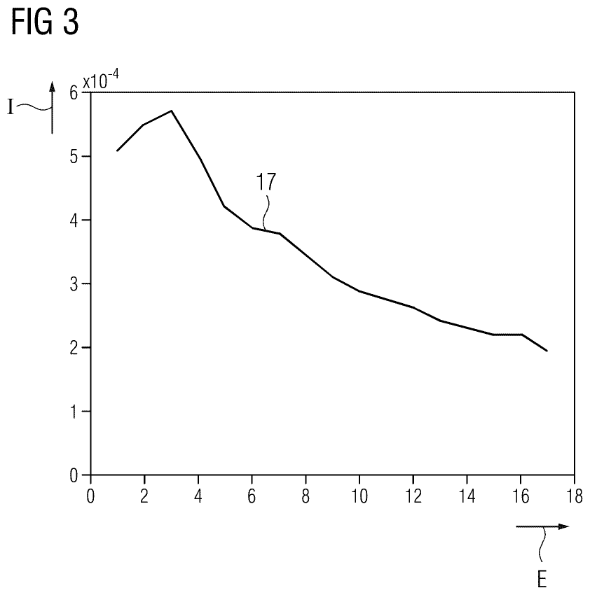

FIG. 2 explains this in more detail for a first example, namely a TSE sequence as a magnetic resonance sequence. In TSE sequences, phase correction scans are frequently performed for eddy current correction before the acquisition of the actual magnetic resonance data. FIG. 2 shows acquisition sections 1, 2, in which a phase correction scan is performed for a first layer and a second layer, wherein the continuation points indicate that further layers can also follow. In the sequence diagram 3 assigned to acquisition section 1, the top graph 4 shows the radio-frequency activity, the second graph 5 readout gradients, the third graph 6 phase-encoding gradients and the fourth graph 7 readout time windows 8 for the acquisition of respective echoes 16. The structure known for multi-echo acquisitions can be discerned, in which echoes 16 arise after a first, common radio-frequency excitation pulse in each case after refocusing pulses 16, which are read out, cf. again readout time window 8.
As shown, no phase-encoding gradients are used in the phase correction scan, so that the magnitude data contains comparable statements about the signal path over the echo train. Thus while the phase data of the phase correction scan is evaluated as normal for eddy current correction, the magnitude data can be employed as measured data in step S2 to determine the path data set.
FIG. 2 also shows the further path, for example acquisition sections 9, 10 of a first shot for the first and the second layer, again where appropriate continued for further layers, which is then correspondingly followed by acquisition sections 11, 12 for the second shot. As can be seen from the sequence diagram 13 of the first shot for the first layer, phase-encoding gradients are employed there, cf. graph 6, in order to sample different k-space rows.
For clarification, FIG. 3 shows a signal path 17 (intensity I) over the echo number E. This is (as regards the readout direction) an averaged signal path 17 in the center of the k-space. However, a determination resolved as regards the readout direction and/or even a determination resolved along the coil dimension is of course also possible.

If the sampling sequence is now known for the further acquisition sections 9, 10, 11, 12, . . . , consequently the k-space trajectory, the signal path 17 can be transferred along the echo dimension to the k-space (in particular thus the phase-encoding direction(s)), since it is known which echo 16 of an echo train is read out along which k-space line. Thus a decay matrix can be determined as a path data set in step S2 in particular, in which a measure for the signal intensity can be assigned to each sampled k-space position when it is sampled, for example a relative weighting.

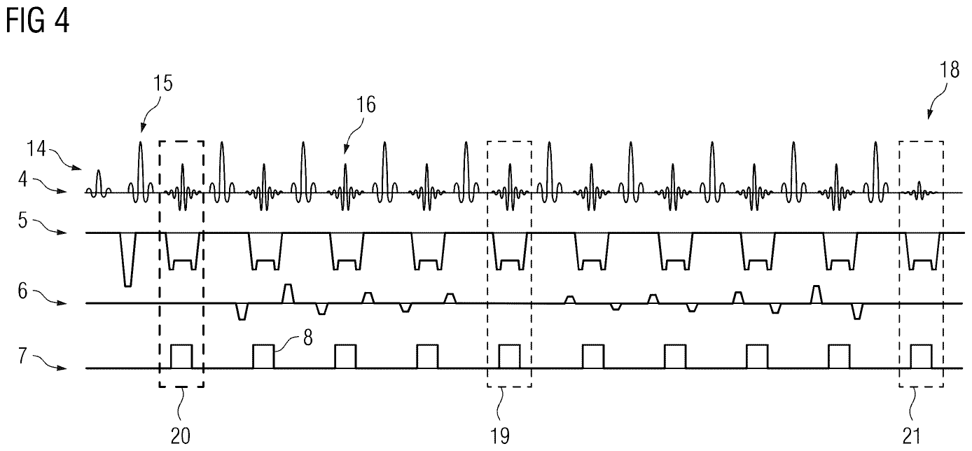

If a magnetic resonance sequence is used which does not contain a phase correction scan, for example a HASTE (half Fourier-acquisition single-shot turbo spin echo) sequence, non-phase-encoded k-space lines can be incorporated in at least one echo train to obtain measured data. This is indicated for example in FIG. 4, which shows a sequence diagram 18 of an echo train of a HASTE sequence. Here the center of the k-space, readout module 19, is acquired without phase-encoding gradients in any case. In addition, the first echo 16, cf. readout module 20, and the last echo 16, cf. readout module 21, are now likewise acquired without phase-encoding gradients in order to obtain additional measured data. From these three (and possibly more) data points, an exponential decay can be determined by interpolation, for example by specifying a decay model, over the echo train, so that here too a signal path 17 as in FIG. 3 results. Alternatively or additionally, it is also conceivable for a particular number of k-space rows to be acquired twice and for the path data set to be determined from the signal evolution.

It should be noted that it is also conceivable in principle for the path data set to be determined at least in part by simulation, calculation and/or modeling even without measured data acquired with the magnetic resonance sequence. Instead or additionally, relaxation information can be used. For example, preliminary measurements of the examination procedure, in particular relaxometry or mapping methods, can be used. From a T2 map, which is for example present layer-by-layer, the decay of the magnetic resonance signal over the entire k-space can likewise be calculated. It is further conceivable for a signal path 17 to be determined from a look-up table containing typical decay values on the basis of the body region and/or the set sequence parameters.

The path data set may be defined as a decay matrix in the k-space, which assigns a decay value as a measure for the signal strength to each sampled k-space position. The dimensions of the path data set then correspond to those of the magnetic resonance data set in the k-space (where the corresponding k-space position is assigned the corresponding k-space value of the magnetic resonance data).

In a step S3, a trained preparation function is applied as a processing function to input data, which may comprise the original magnetic resonance data set as well as the path data set, in particular formed therefrom. As a result, the trained preparation function provides a corrected magnetic resonance data set which corresponds to a reference path, in particular a single echo measurement, where the differences in signal intensities from echo to echo are no longer present or at least are reduced. In other words, the corrected magnetic resonance data set is corrected for the decay of the magnetic resonance signal in accordance with the signal path 17 which deviates from the reference path. In a single echo measurement, the same signal intensity is to be expected for each echo (and the same signal path along the readout direction every time).

FIG. 5 shows a specific configuration in which the trained preparation function 22 is designed as CNN, specifically as U-Net. The input data is formed by the original magnetic resonance data set 23 in the k-space and by the path data set 24 in the k-space. The corrected magnetic resonance data set 25 results in the k-space as output data.

The U-Net may comprise, as schematically shown and known in principle, an encoder arm 26 and a decoder arm 27. Skip connections 28 exist between the layers of the arms 26, 27.

Generally speaking, the U-Net may comprise pooling layers and upsampling layers in addition to convolution layers. Along the encoder arm, the input data, in particular at least of the original magnetic resonance data set 23, is first downsampled, after which it is upsampled again along the decoder arm 27 in order to obtain the corrected magnetic resonance data set 25. The resulting U-shaped architecture gives the U-Net its name.

In other exemplary embodiments other network architectures of the preparation function 22 are also conceivable.

Returning to FIG. 1, the corrected magnetic resonance data set 25 serves as input data for a trained application function, here for example a resolution enhancement function, where appropriate after a Fourier transform into the image space. For example, it can be a super-resolution function. The resolution enhancement function was trained with training data that had the reference path, so that optimal processing results can be obtained, which can then be provided.

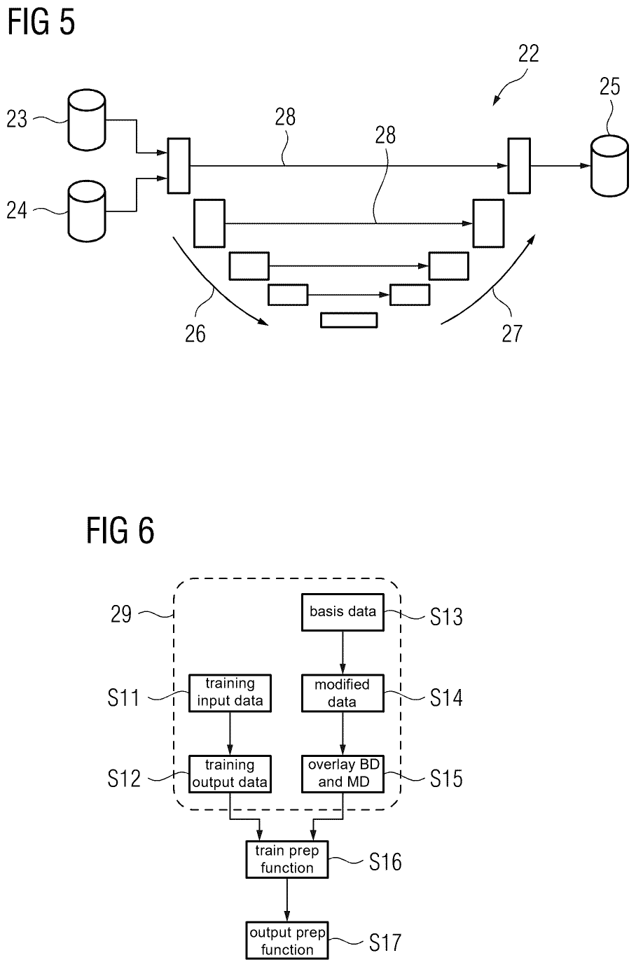

FIG. 6 schematically shows a possible operational sequence for training the preparation function 22. In this, preparation function training data sets are first compiled in a step group 29. Multiple ways to do this exist, and can be used alternatively or else as a supplement.

In a first approach, in a step S11 training input data sets are measured in a first training measurement and training output data sets are measured in a second training measurement on the same object (S12). In this case, anatomical phantoms, fruits and vegetables serve as measurement objects, since they are very similar in their decay properties and structure to acquisition areas of the human body, but neither move between the first and second training measurement nor change in any other way, for example due to physiological processes. In the example set out above, a first training measurement can for example take place with a TSE sequence with turbo factor 8 in order to derive a magnetic resonance data set subject to a signal path 17 therefrom and a path data set as a training input data set. The second training measurement can then take place with turbo factor 1, i.e. as a single echo measurement, wherein however the same echo time is used. In this case the reference path is thus the single echo measurement. However, it is also conceivable for non-perfect target k-spaces to be targeted, for example thus for the first training measurement to be performed with a turbo factor of 16 and the second training measurement with a turbo factor of 4, consequently using another reference. In the HASTE sequence, the echo train length can for example be shortened by parallel imaging.

In another possible way to compile preparation function training data sets, a basic data set which contains no noise due to synthesis or for example very little noise due to a preceding denoising operation is provided in a step S13. This basic data set can now easily be modified immediately in a step S14 with different path data sets in order to obtain modification data sets due to the non-existent or extremely low noise. If the path data sets are decay matrices with weightings as decay values, a simple multiplication of the basic data set by the path data set can take place. In a step S15, each pair of basic data set and modification data set is then overlaid with Gaussian noise of equal distribution in order to obtain preparation function training data sets with a preparation function training output data set and a preparation function training input data set in each case.

In a step S16, the preparation function training data sets are used to train the preparation function 22. The trained preparation function 22 can then be provided in a step S17.

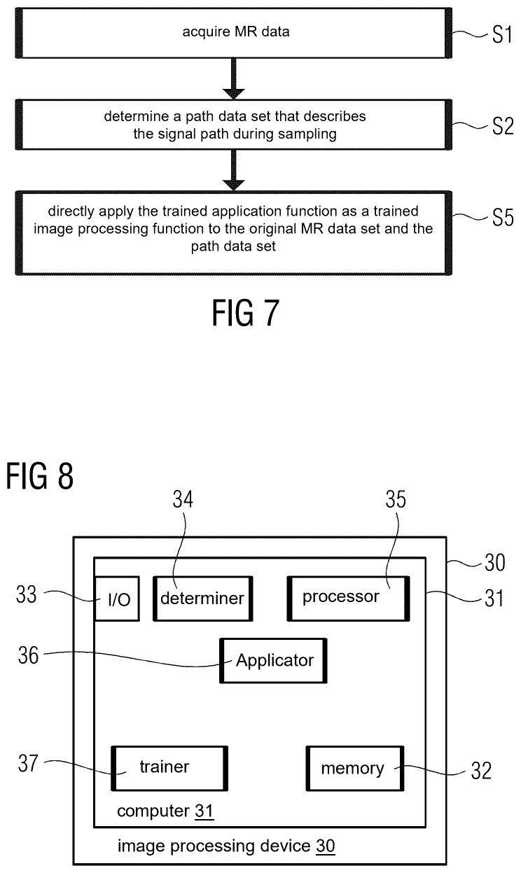

The flowchart in FIG. 7 explains a second, modified exemplary embodiment of the inventive processing method. Whereas steps S1 and S2 serve for the acquisition of the magnetic resonance data set 23/the measured data and the determination of the path data set 24 without change, these are now provided in a step S5 directly to the correspondingly modified application function, here again a trained resolution enhancement function. The resolution enhancement function thus uses the path data set as additional input data and performs the correction around the path internally. Suitable training data can also be obtained here for example by first and second training measurements.

Finally, FIG. 8 shows an inventive image processing facility (image processor) 30 as well as the functional structure of its computing facility 31. The image processing facility 30 can be integrated into a magnetic resonance facility, in particular by integrating the computing facility 31 into its control facility (controller). In an exemplary embodiment, the image processing facility (image processor) 30 can include processing circuitry that is configured to perform one or more functions and/or operations of the image processing facility (image processor) 30. Additionally, or alternatively, one or more components of the image processing facility (image processor) 30 may include processing circuitry that is configured to perform function(s) and/or operation(s) of the respective component(s).

The computing facility 31 may comprise at least one processor and at least one storage means 32. Magnetic resonance data and measured data can be obtained via an interface 33. In the case of a control facility of a magnetic resonance facility, this can have a sequence unit which controls the acquisition operation and via the interface 33 provides the original magnetic resonance data set 23 as well as the measured data from which the path data set 24 is to be determined. Further information can also be obtained via the interface 33, for example sequence parameters, relaxation information and the like.

In a determination unit 34, the path data set 24 is determined in accordance with step S2. Since in the present case the configuration is shown by way of example for the performance of the method in accordance with the first exemplary embodiment (FIG. 1), a processing unit 35 is used to apply the preparation function 22 to the original magnetic resonance data set 23 and the path data set 24 in accordance with step S3. In an application unit 36, the application function can then be applied to the corrected magnetic resonance data set 25 in accordance with step S4.

In alternative configurations, used for the performance of the method in accordance with FIG. 7, the processing unit 35 is designed to directly apply the trained application function as a trained image processing function to the original magnetic resonance data set 23 and the path data set 24 in accordance with step S5.

Processing results, in particular the output data of the application function, can be provided via the interface 33 or an additional interface.

The computing facility 31 can also have a training unit (trainer) 37 as a further function unit, for example to train the preparation function 22, as described with regard to FIG. 6. It is of course also possible to use a separate provision system or training system.

It should be noted that the procedure described here can also be applied to other applications besides multi-echo measurements, in which a relevant signal path, which in particular differs from other magnetic resonance sequences, is present over an acquisition period. One example is UTE sequences, in which the path data set can for example refer to the k-space row of an echo.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A computer-implemented method for processing a magnetic resonance data set of an acquisition area associated with an acquisition in an examination procedure in a magnetic resonance facility with a magnetic resonance sequence in which multiple echoes are acquired in an echo train, after a common radio-frequency excitation pulse, the method comprising:
determining, for the magnetic resonance data set, a path data set describing a signal path of a measured magnetic resonance signal over an acquisition period in the magnetic resonance sequence in k-space; and
transferring the determined path data set together with the magnetic resonance data set as input data to a trained image processing function to determine a result data set.

2. The method as claimed in claim 1, wherein the path data set is at least in part determined from measured data of a measurement of the examination procedure.

3. The method as claimed in claim 2, further comprising using, as the measured data:
magnitude data of a phase correction scan with the magnetic resonance sequence, which was acquired without phase-encoding gradients;
additional measured data of particular echoes of an echo train, which was acquired without phase-encoding gradients; and/or
repetition measured data for at least one k-space section measured multiple times during the echo train.

4. The method as claimed in claim 1, wherein the path data set is determined at least in part by a calculation, modeling, and/or simulation, and wherein at least one item of relaxation information about the relaxation in the acquisition area is used in the determination of the path data set.

5. The method as claimed in claim 4, wherein the relaxation information comprises at least one T2 and/or T2* relaxation time and/or is determined at least in part based on: a map measured previously; relaxometry measurement of the acquisition area; and/or an assignment rule which assigns at least some of the relaxation information to an item of information about an anatomical position of the acquisition area and/or about a material composition of the acquisition area.

6. The method as claimed in claim 1, wherein the path data set is determined based on measured data, measured along a readout direction of the magnetic resonance sequence and/or measured for different local coil elements of a local coil array used.

7. The method as claimed in claim 1, wherein the trained image processing function is a preparation function, which as output data, outputs a corrected magnetic resonance data set whose signal path corresponds to a reference path.

8. The method as claimed in claim 7, wherein the corrected magnetic resonance data set is used as input data for a trained application function, wherein the application function is trained with application function training data sets whose application function training input sets have the reference path.

9. The method as claimed in claim 7, wherein the preparation function comprises a convolutional neural network.

10. The method as claimed in claim 7, wherein, for training the preparation function:
determining preparation function training data sets by:
providing, in k-space, a synthesized and/or noise-free basic data set of the reference path,
applying at least one training path data set to the basic data set to determine a modification data set, and
providing the modification data set and the basic data set with noise to obtain a preparation function training input data set or a preparation function training output data set;
acquiring preparation function training input data sets in a first training measurement and acquiring preparation function training output data sets with a second training measurement using the reference path; and/or
determining at least some of the preparation function training data by simulation using the reference path.

11. The method as claimed in claim 1, wherein the trained image processing function is an application function to determine the result data set as output data.

12. The method as claimed in claim 10, wherein stationary measurement objects are used to perform training measurements to obtain training input data and training output data in consecutive measurement procedures.

13. At least one non-transitory computer-readable medium comprising instructions stored thereon, that when executed by one or more processors, cause the one or more processors to perform the method of claim 1.

14. An image processing device comprising:
a processor; and
memory storing instructions that, when executed by the processor, cause the image processing device to:
determine a path data set in k-space describing a signal path of a measured magnetic resonance signal over an acquisition period in a magnetic resonance sequence for a magnetic resonance data set of an acquisition area associated with an acquisition in an examination procedure in a magnetic resonance facility, wherein the acquisition includes multiple echoes acquired in an echo train after a common radio-frequency excitation pulse; and
determine a result data set using a trained image processing function and based on the path data set and the magnetic resonance data set as input data.
